(19) United States
(12) Patent Application Publication
(10) Pub. No.: US 2025/0127068 A1
(43) Pub. Date: Apr. 17, 2025

(54) RESISTIVE RANDOM-ACCESS MEMORY (RRAM) DEVICES WITH ELECTRODES CONTAINING RUTHENIUM

(71) Applicant: TetraMem Inc., Fremont, CA (US)

(72) Inventors: Minxian Zhang, Amherst, MA (US); Mingche Wu, San Jose, CA (US); Ning Ge, Danville, CA (US)

(73) Assignee: TetraMem Inc., Fremont, CA (US)

(21) Appl. No.: 18/485,209

(22) Filed: Oct. 11, 2023

(51) Int. Cl. H10N 70/00; H10B 63/00; H10N 70/20

(52) U.S. Cl. CPC H10N 70/8416; H10B 63/00; H10N 70/011; H10N 70/24; H10N 70/8833

(57) ABSTRACT

The present disclosure provides resistive random-access memory (RRAM) devices and methods for making the same. An RRAM device may include a first electrode, a second electrode comprising ruthenium, and a switching oxide layer fabricated between the first electrode and the second electrode. The first electrode includes at least one of palladium, titanium nitride, or tantalum nitride. The switching oxide layer comprises at least one transition metal oxide. In some embodiments, the RRAM device further includes an interface layer positioned between the switching oxide layer and the second electrode and/or an interface layer positioned between the first electrode and the switching oxide layer.

### TECHNICAL FIELD

The implementations of the disclosure relate generally to resistive random-access memory (RRAM) devices and, more specifically, to RRAM devices with electrodes containing ruthenium (Ru) and methods for fabricating the same.

### BACKGROUND

A resistive random-access memory (RRAM) device is a two-terminal passive device with tunable and non-volatile resistance. The resistance of the RRAM device may be electrically switched between a high-resistance state (HRS) and a low-resistance state (LRS) by applying suitable programming signals to the RRAM device. RRAM devices may be used to form crossbar arrays that may be used to implement in-memory computing applications, non-volatile solid-state memory, image processing applications, neural networks, etc.

### SUMMARY

The following is a simplified summary of the disclosure to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

According to one or more aspects of the present disclosure, a resistive random-access memory (RRAM) device includes a first electrode, a second electrode including ruthenium, and a switching oxide layer fabricated between the first electrode and the second electrode. The first electrode includes at least one of palladium, titanium nitride, or tantalum nitride.

The switching oxide layer includes at least one transition metal oxide. In some embodiments, the transition metal oxide includes at least one of HfOₓ or TaO_{y}, wherein x≤2.0, and wherein y≤2.5.

In some embodiments, the switching oxide layer further includes a dopant oxide that is more chemically stable than the at least one transition metal oxide.

In some embodiments, the dopant oxide includes at least one of Al₂O₃, SiO₂, ZrO₂, Sc₂O₃, or Y₂O₃.

In some embodiments, the second electrode further includes a layer of at least one of a complementary metal-oxide-semiconductor (CMOS) compatible metal or a CMOS-compatible nitride. The CMOS-compatible metal includes at least one of tungsten, titanium, aluminum, or copper. The CMOS-compatible nitride includes at least one of silicon nitride, aluminum nitride, tantalum nitride, or titanium nitride.

In some embodiments, further including an interface layer positioned between the switching oxide layer and the second electrode, wherein the second electrode including ruthenium is fabricated on the interface layer.

In some embodiments, the interface layer includes a non-continuous film of a dielectric material, wherein at least a portion of the ruthenium in the second electrode is deposited on the switching oxide layer. The dielectric materials include at least one of Al₂O₃, SiO₂, Si₃N₄, MgO, Y₂O₃, Gb₂O₃, Sm₂O₃, CeO₂, Er₂O₃, or La₂O₃.

In some embodiments, the RRAM device further includes a first interface layer positioned between the first electrode and the switching oxide layer.

In some embodiments, the RRAM device further includes a second interface layer positioned between the second electrode and the switching oxide layer.

In some embodiments, a conductive channel including ruthenium is formed in the switching oxide layer in response to an application of a programming voltage to the RRAM device.

According to one or more aspects of the present disclosure, methods for fabricating an RRAM device include: fabricating a first electrode including at least one of palladium, titanium nitride, or tantalum nitride; fabricating a switching oxide layer on the first electrode, wherein the switching oxide layer includes at least one transition metal oxide; and fabricating a second electrode including ruthenium.

In some embodiments, fabricating the second electrode includes fabricating a layer of ruthenium.

In some embodiments, fabricating the second electrode further includes fabricating a layer of at least one of a CMOS-compatible metal or a CMOS-compatible nitride, wherein the CMOS-compatible metal includes at least one of tungsten, titanium, aluminum, or copper, wherein the CMOS-compatible nitride includes at least one of silicon nitride, aluminum nitride, tantalum nitride, or titanium nitride.

In some embodiments, the methods further include fabricating an interface layer on the switching oxide layer, wherein fabricating the second electrode includes depositing ruthenium on the interface layer.

In some embodiments, the interface layer includes a non-continuous film of a dielectric material, wherein at least a portion of the ruthenium in the second electrode is deposited on the switching oxide layer.

In some embodiments, the methods further include fabricating a first interface layer including a first dielectric material on the first electrode, wherein the switching oxide layer is fabricated on the first interface layer.

In some embodiments, the methods further include fabricating a second interface layer including a second dielectric material on the switching oxide layer, wherein the second electrode is fabricated on the second interface layer.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding.

FIG. 1 is a schematic diagram illustrating an example of a crossbar circuit in accordance with some embodiments of the present disclosure.

FIG. 2 is a schematic diagram illustrating an example of a cross-point device in accordance with some embodiments of the present disclosure.

FIGS. 3A, 3B, 3C, 3D, 3E, and 3F illustrate cross-sectional views of structures for fabricating an RRAM device in accordance with some embodiments of the present disclosure.

FIGS. 4A, 4B, 4C, 4D, 4E, 4F, 5A, 5B, 5C, 5D, 6A, 6B, 6C, and 6D are schematic diagrams illustrating cross-sectional views of example structures of RRAM devices in accordance with some embodiments of the present disclosure.

FIGS. 7, 8, 9, and 10 are flow diagrams illustrating example processes for fabricating RRAM devices according to some embodiments of the disclosure.

FIG. 11 is a Pd—Ru binary phase diagram.

### DETAILED DESCRIPTION

Aspects of the disclosure provide resistive random-access memory (RRAM) devices and methods for fabricating the RRAM devices. RRAM devices (also referred to as memristors) are a type of two-terminal electronic device exhibiting both memory and non-volatile resistance. The switching parameters and device performance of memristors are determined by their mobile species and matrix materials. RRAM devices utilizing oxygen ions or oxygen vacancies as the mobile species usually exhibit great retention, but also need relatively high switching energy (voltage, current). This is because oxygen ions are relatively large and slow to move substitutionally in the oxide. RRAM devices with Ag or Cu as cation mobile species do not require high switching energy but usually show poor retention. This is because Ag and Cu ions are relatively small and fast to move interstitially in oxide, but they are also more likely to diffuse away from the switching layer over time.

Ruthenium (Ru) serves as a desirable mobile species for RRAM devices, enabling low switching energy, fast speed, good retention, reliability, scalability, and analog switching properties simultaneously. Existing RRAM devices that utilize Ru ions as a mobile species typically comprise an electrode containing platinum (Pt), an electrode containing Ru, and a switching oxide positioned between the electrodes. In these existing RRAM devices, Ru migrations can occur between the Ru electrode and the switching oxide and between the oxide and the Pt electrode due to the substantial solubility of Ru in the Pt phase. In particular, the solubility of Ru in Pt is about 60 at % at 500° C. and may exceed 50 at % at room temperature. During a set operation, Ru ions might migrate from the Ru electrode to the switching oxide, achieving the desired conductivity. However, some Ru ions might also migrate from the switching oxide to the Pt electrode. During a reset operation, some Ru ions might migrate from the switching oxide back to the Ru electrode, but others might migrate from the Pt electrode to the switching oxide. These undesired Ru migrations between the switching oxide and the Pt electrode can cause resistance variations in the RRAM devices, leading to switching inconsistencies or variations. For instance, if more Ru ions migrate from the Ru electrode to the oxide during the set operation than from the oxide to the Pt electrode, the device will exhibit lower resistance. Conversely, if more Ru ions migrate from the oxide to the Pt electrode during the set operation than from the Ru electrode to the oxide, the device will exhibit higher resistance. Such switching variations pose challenges for devices requiring consistent resistance, like memory and logic devices.

In view of the above and other deficiencies of the existing RRAM devices, the present disclosure provides RRAM devices utilizing Ru as mobile species. In some embodiments, an RRAM device may include a first electrode including a non-reactive electrode material, a second electrode (e.g., a reactive electrode), and a switching oxide layer between the two electrodes. The second electrode may include Ru. In some embodiments, the first electrode may include TiN and/or TaN. In some embodiments, the first electrode may include palladium (Pd). In some embodiments, the RRAM device further includes an interface layer positioned between the switching oxide layer and the second electrode and/or an interface layer positioned between the first electrode and the switching oxide layer.

The electrode material in the first electrode has low solubility for Ru, ensuring minimal Ru migration between the first electrode (the non-reactive electrode) and the switching oxide. Additionally, the oxide formed by non-reactive electrode material is less stable than the switching oxide, ensuring it does not absorb oxygen from the switching oxide. In addition, the oxide of the non-reactive electrode material is conductive, preventing an increase in contact resistance at the electrode/oxide interface.

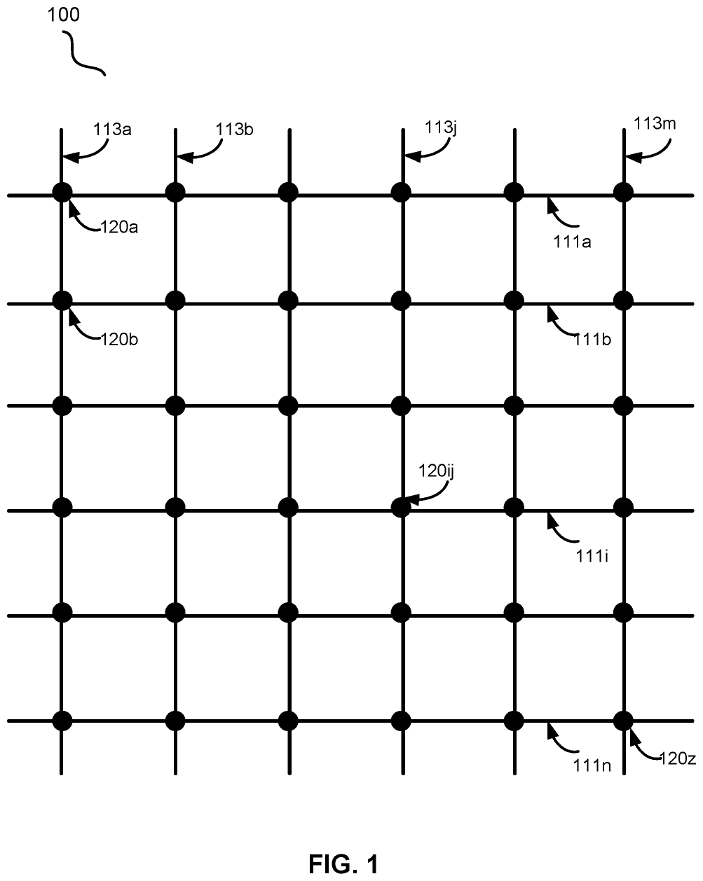

FIG. 1 is a schematic diagram illustrating an example 100 of a crossbar circuit in accordance with some embodiments of the present disclosure. As shown, crossbar circuit 100 may include a plurality of interconnecting electrically conductive wires, such as one or more row wires 111a, 111b, . . . , 111i, . . . , 111n, and column wires 113a, 113b, . . . , 113j, . . . , 113m for an n-row by m-column crossbar array. The crossbar circuit 100 may further include cross-point devices 120a, 120b, . . . , 120z, etc. Each of the cross-point devices may connect a row wire and a column wire. For example, the cross-point device 120ij may connect the row wire 111i and the column wire 113j. In some embodiments, crossbar circuit 100 may further include digital to analog converters (DAC, not shown), analog to digital converters (ADC, not shown), switches (not shown), and/or any other suitable circuit components for implementing a crossbar-based apparatus. The number of the column wires 113a-m and the number of the row wires 111a-n may or may not be the same.

Row wires 111a-n may include a first row wire 111a, a second row wire 111b, . . . , 111i, . . . , and an n-th row wire 111n. Each of row wires 111a, . . . , 111n may be and/or include any suitable electrically conductive material. In some embodiments, each row wire 111a-n may be a metal wire.

Column wires 113a-m may include a first column wire 113a, a second column wire 113b, . . . , and an m-th column wire 113m. Each of column wires 113a-m may be and/or include any suitable electrically conductive material. In some embodiments, each column wire 113a-m may be a metal wire.

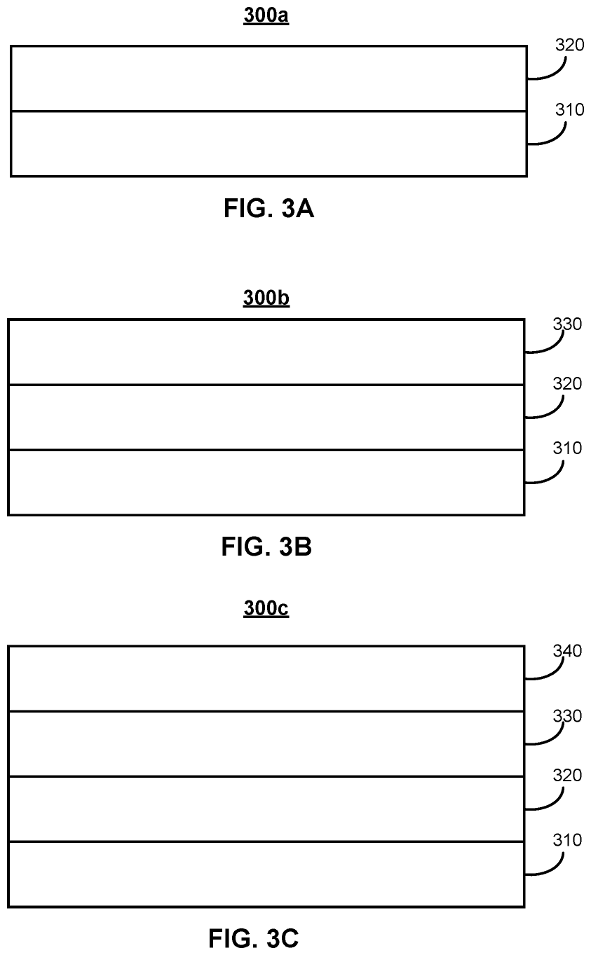

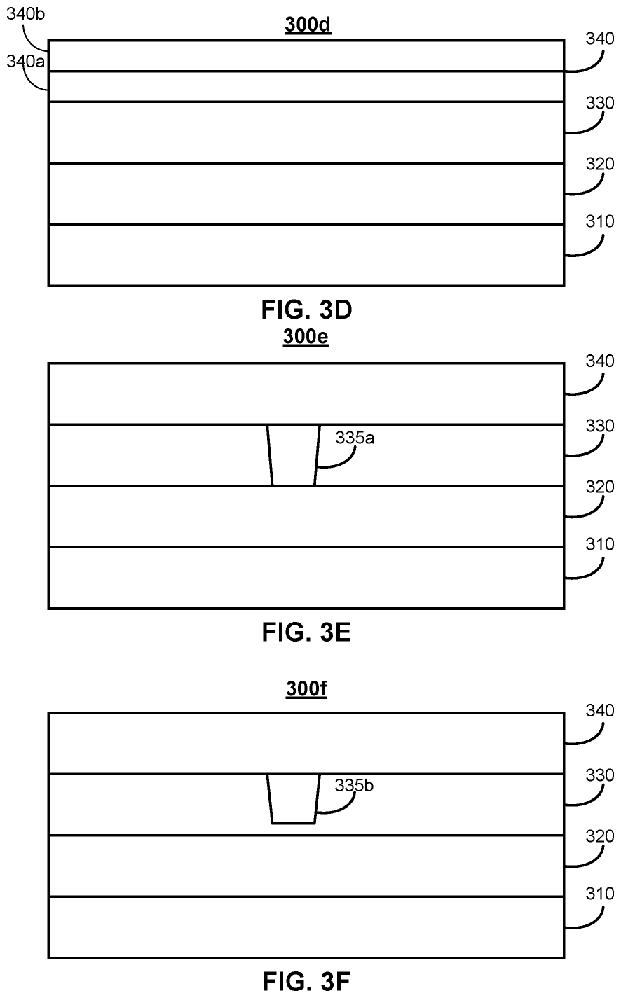

Each cross-point device 120a-z may be and/or include any suitable device with tunable resistance, such as a memristor, PCM (phase change memory) devices, floating gates, spintronic devices, resistive random-access memory (RRAM), static random-access memory (SRAM), etc. In some embodiments, one or more cross-point devices 120a-z may include an RRAM device as described in connection with FIGS. 3A-6D.

Crossbar circuit 100 may perform parallel weighted voltage multiplication and current summation. For example, an input voltage signal may be applied to one or more rows of crossbar circuit 100 (e.g., one or more selected rows). The input signal may flow through the cross-point devices of the rows of the crossbar circuit 100. The conductance of the cross-point device may be tuned to a specific value (also referred to as a “weight”). By Ohm's law, the input voltage multiplies the cross-point conductance and generates a current from the cross-point device. By Kirchhoff's law, the summation of the current passing the devices on each column generates the current as the output signal, which may be read from the columns (e.g., outputs of the ADCs). According to Ohm's law and Kirchhoff's current law, the input-output relationship of the crossbar array can be represented as I=VG, wherein I represents the output signal matrix as current; V represents the input signal matrix as voltage; and G represents the conductance matrix of the cross-point devices. As such, the input signal is weighted at each of the cross-point devices by its conductance according to Ohm's law. The weighted current is output via each column wire and may be accumulated according to Kirchhoff's current law. This may enable in-memory computing (IMC) via parallel multiplications and summations performed in the crossbar arrays.

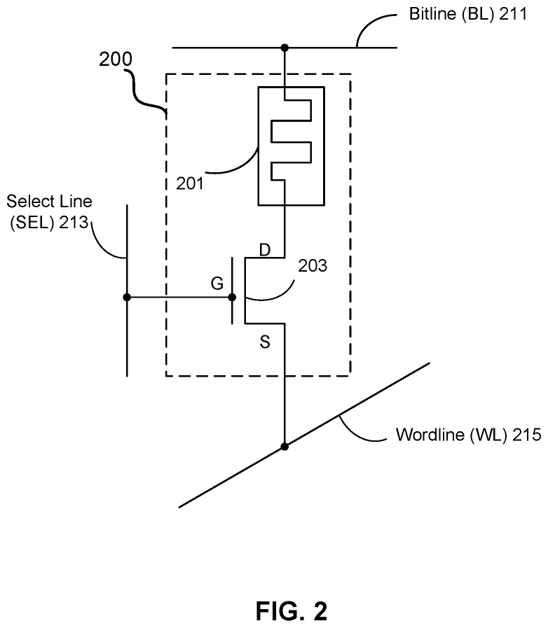

FIG. 2 is a schematic diagram illustrating an example 200 of a cross-point device in accordance with some embodiments of the present disclosure. As shown, cross-point device 200 may connect a bitline (BL) 211, a select line (SEL) 213, and a wordline (WL) 215. The bitline 211 and the wordline 215 may be a column wire and a row wire as described in connection with FIG. 1, respectively.

Cross-point device 200 may include an RRAM device 201 and a transistor 203. A transistor may include three terminals, which may be marked as gate (G), source(S), and drain (D), respectively. The transistor 203 may be serially connected to RRAM device 201. As shown in FIG. 2, the first electrode of the RRAM device 201 may be connected to the drain of transistor 203. The second electrode of the RRAM device 201 may be connected to the bitline 211. The source of the transistor 203 may be connected to the wordline 215. The gate of the transistor 203 may be connected to the select line 213. RRAM device 201 may include one or more RRAM devices as described in connection with FIGS. 3A-6D below. Cross-point device 200 may also be referred to as a one-transistor-one-resistor (1T1R) configuration. The transistor 203 may perform as a selector as well as a current controller, which may set the current compliance to the RRAM device 201 during programming. The gate voltage on transistor 203 can set current compliances to cross-point device 200 during programming and can thus control the conductance and analog behavior of cross-point device 200. For example, when cross-point device 200 is set from a high-resistance state to a low-resistance state, a set signal (e.g., a voltage signal, a current signal) may be provided via the bitline (BL) 211. Another voltage, also referred to as a select voltage or gate voltage, may be applied via the select line (SEL) 213 to the transistor gate to open the gate and set the current compliance, while the wordline (WL) 215 may be set to ground. When cross-point device 200 is reset from the low-resistance state to the high-resistance state, a gate voltage may be applied to the gate of the transistor 203 via the select line 213 to open the transistor gate. Meanwhile, a reset signal may be sent to the RRAM device 201 via the wordline 215, while the bitline 211 may be set to ground.

FIGS. 3A, 3B, 3C, and 3D illustrate cross-sectional views of structures 300a, 300b, 300c, and 300d for fabricating an RRAM device in accordance with some embodiments of the present disclosure. FIGS. 3E and 3F illustrate RRAM devices 300e and 300f corresponding to RRAM devices 300c-d at a low resistance state (LRS) and a high resistance state (HRS), respectively.

As shown in FIG. 3A, a substrate 310 may be provided. A first electrode 320 may be fabricated on the substrate 310. The substrate 310 may include one or more layers of any suitable material that may serve as a substrate for an RRAM device, such as silicon (Si), silicon dioxide (SiO₂), silicon nitride (Si₃N₄), aluminum oxide (Al₂O₃), aluminum nitride (AlN), etc. In some embodiments, the substrate 310 may include diodes, transistors, interconnects, integrated circuits, one or more other RRAM devices, etc. In some embodiments, the substrate 310 May include a driving circuit including one or more electrical circuits (e.g., an array of electrical circuits) that may be individually controllable. In some embodiments, the driving circuit may include one or more complementary metal-oxide-semiconductor (CMOS) drivers.

The first electrode 320 may include any suitable material that is electronically conductive, non-reactive to the switching oxide layer to be fabricated on the first electrode 320, and non-reactive to the mobile species Ru during RRAM operations (also referred to as the “non-reactive” material). As an example, the first electrode 320 may include a non-reactive metal, such as palladium (Pd), etc. As another example, the first electrode 320 may include a metal nitride having suitable chemical stability so that it will not react with oxygen and Ru during RRAM switching, such as titanium nitride (TiN), tantalum nitride (TaN), etc. The first electrode 320 may also be referred to as the “non-reactive electrode.”

Referring to FIG. 3B, a switching oxide layer 330 may be fabricated on the first electrode 320. The switching oxide layer 330 may include one or more transition metal oxides, such as TaOₓ, HfOₓ, TiOₓ, NbOₓ, ZrOₓ, etc., in binary oxides, ternary oxides, and high-order oxides. In some embodiments, the chemical stability of the non-reactive material in the first electrode 320 may be higher than that of metal in the transition metal oxide(s) in switching oxide layer 330. In some embodiments, the transition metal oxide(s) include at least one of HfOₓ or TaOₓ, wherein x may be used to indicate the oxide being oxygen deficient compared to its full (or terminal) oxide and the value of x may be varied from the oxygen to metal atomic ratio in the stoichiometry of its full oxide, such as x≤2.0 for HfOₓ (where HfO₂ being the full oxide), and x≤2.5 for TaOₓ (where Ta₂O₅ being the full oxide).

As shown in FIG. 3C, a second electrode 340 may be fabricated on the switching oxide layer 330 to fabricate an RRAM device 300c. The second electrode 340 may include ruthenium (Ru) (e.g., Ru metal). The second electrode 340 may also be referred to as the “reactive electrode,” since Ru can migrate between the second electrode and the switching oxide during RRAM switching.

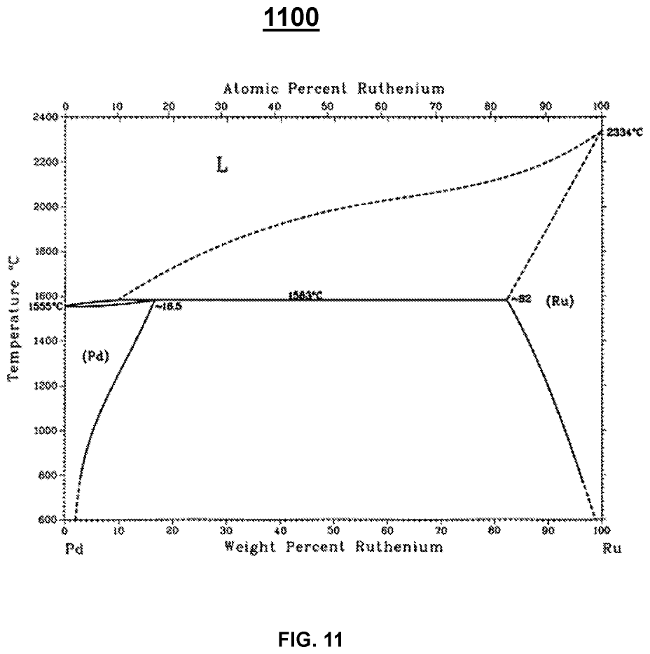

In one implementation, the first electrode 320 and the second electrode 340 may include Pd and Ru, respectively. The Pd—Ru binary phase diagram 1100 of FIG. 11 shows that the Pd solid phase and the Ru solid phase are almost immiscible, meaning that they do not tend to form a solid solution. This means that the solubility of Ru in Pd is very low, approximately 2at % at 500° C. This solubility is likely to be even lower at room temperature. This low solubility of Ru in Pd suggests that using a Pd electrode could significantly reduce Ru migration between the first electrode and the switching oxide. This is because there is a much limited composition range—for Ru to diffuse into the Pd electrode. By reducing Ru migration between the first electrode and the switching oxide, a Pd electrode may reduce switching variations in RRAM devices. This is because the switching mechanism would be simplified, as Ru migration would only need to occur between the Ru electrode and the switching oxide, and not between the Pd electrode and the switching oxide.

In another implementation, the second electrode 340 contains Ru and the first electrode 320 contains at least one of TiN or TaN. The reactions where TiN combines with Ru to form RuN and Ti, as well as when TaN reacts with Ru to produce RuN and Ta, are not expected to spontaneously occur due to this enthalpic consideration. That is, the following reactions would not occur spontaneously:

TiN +Ru=RuN+Ti

TaN+Ru=RuN+Ta

This is because ruthenium nitride (RuN) presents a positive enthalpy of formation under ambient conditions and would not form when Ru encounters TiN or TaN electrodes. This positive enthalpy indicates certain limitations in the thermodynamic stability of RuN and the non-reactivity between Ru and TiN or TaN.

In some embodiments, as shown in FIG. 3D, second electrode 340 may include a layer 340a of Ru and a layer 340b of one or more CMOS-compatible metals and/or nitrides that can be integrated into the CMOS (Complementary Metal-Oxide-Semiconductor) fabrication processes without causing detrimental effects on the device performance. Examples of CMOS-compatible metals include Tungsten (W), Titanium (Ti), Aluminum (Al), Copper (Cu), etc. Examples of CMOS-compatible nitrides include silicon nitride (Si3N4), aluminum nitride (AlN), titanium nitride (TiN), tantalum (TaN), etc.

RRAM device 300c-d may have an initial high resistance (also referred to herein as the “virgin resistance”) after it is fabricated. The initial resistance of RRAM device 300c-d may be changed, and RRAM device 300c-d may be switched to a state of a lower resistance via a forming process. For example, a suitable voltage or current may be applied to RRAM device 300c-d. The application of the voltage to RRAM device 300c-d may induce the mobile Ru ions in the second electrode 340 to migrate to the switching oxide layer 330. As a result, a conductive channel (e.g., a filament) of Ru may form in the switching oxide layer 330. For example, as illustrated in FIG. 3E, a Ru conductive channel 335a may be formed in the switching oxide layer 330. The conductive channel 335a may be formed from the second electrode 340 to the first electrode 320 across the switching oxide layer 330. As shown, the conductive channel 335a may directly contact the first electrode 320. As such, the first electrode 320 and the second electrode 340 may be connected via the conductive channel 335a and the conductive material.

RRAM device 300e may be reset to a high-resistance state. For example, a reset signal (e.g., a voltage signal or a current signal) may be applied to RRAM device 300e during a reset process. In some embodiments, the set signal and the reset signal may have opposite polarity, i.e., a positive signal and a negative signal, respectively, for the directional drift of the Ru ions in the switching oxide during the set and/or reset operation. The application of the reset signal may cause some Ru ions in Ru channel 335a to migrate back to the second electrode 340. For example, an interrupted Ru channel 335b as shown in FIG. 3F may be formed in switching oxide layer 330 during the reset process. As shown, the conductive channel may be interrupted with an oxide gap between the interrupted conductive channel 335b and the first electrode 320. In some embodiments, the interrupted conductive channel 335b does not continuously connect the first electrode 320 and the second electrode 340. RRAM device 300c-d may be electrically switched between the high-resistance state and the low-resistance state by applying suitable programming signals (e.g., voltage signals, current signals, etc.) to the RRAM device.

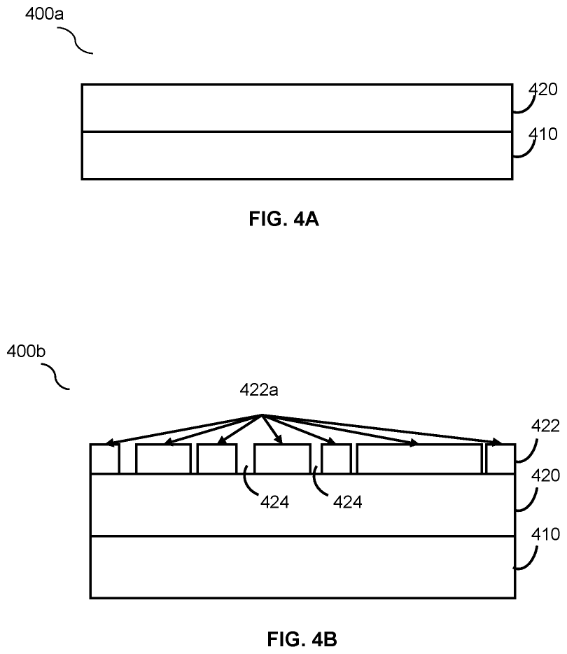

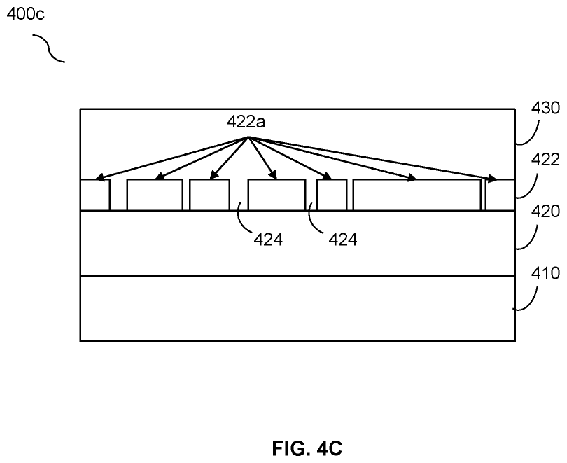

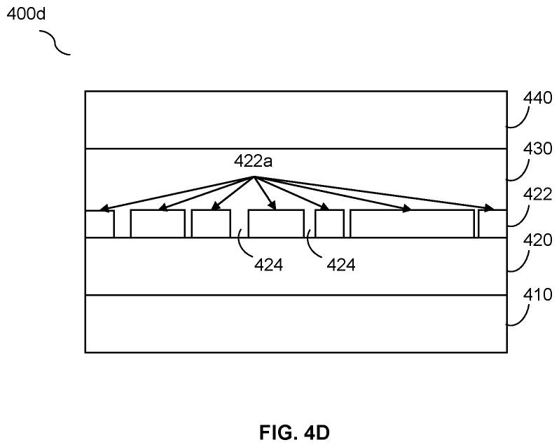

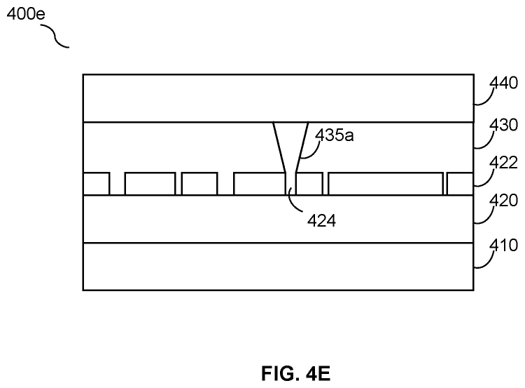

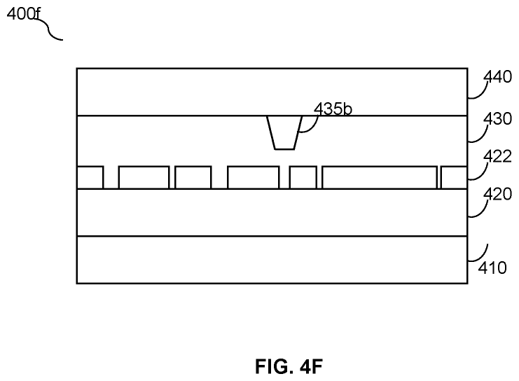

FIGS. 4A-4F are schematic diagrams illustrating cross-sectional views of example structures 400a, 400b, 400c, 400d, 400e, and 400f of RRAM devices in accordance with some embodiments of the present disclosure.

As illustrated FIG. 4A, a first electrode 420 may be fabricated on a substrate 410. The first electrode 420 and the substrate 410 may correspond to the first electrode 320 and the substrate 310 as described in conjunction with FIG. 3A, respectively.

As illustrated FIG. 4B, an interface layer 422 (also referred to as the “first interface layer”) may be fabricated on the first electrode 420. The interface layer 422 may be and/or include a discontinuous film 422a of a first dielectric material that is more chemically stable than the transition metal oxide(s) in the switching oxide layer to be fabricated on the interface layer 422. As a result, the dielectric material may not react with the transition metal oxide(s) in the switching oxide layer. In some embodiments, the first dielectric material may include a metallic element that has a single valence state. As an example, the switching oxide layer may include one or more transition metal oxides, such as at least one of HfOₓ or TaO_{y}, wherein x<2.0, and wherein y≤2.5, and the dielectric material may include one or more of Al₂O₃, SiO₂, Si₃N₄, MgO, Y₂O₃, Gb₂O₃, Sm₂O₃, CeO₂, Er₂O₃, La₂O₃, etc. The dielectric material does not react with the transition metal oxide containing HfO₂ or Ta₂O₅ during setting processes and resetting processes.

As shown, the discontinuous film 422a may include pores and/or pin-holes 424 that are randomly dispersed in the interface layer 422. While a certain number of pores are illustrated in FIG. 4B, this is merely illustrative. The discontinuous film 422a may include any suitable number of pores and/or pin-holes. In some embodiments, a thickness of the interface layer 422 and/or the discontinuous film 422a may be between about 0.2 nm and about 0.5 nm. In some embodiments, the discontinuous film 422a may be an Al₂O₃ film having a thickness equal to or less than 0.5 nm. In some embodiments, the discontinuous film 422a may be and/or include an Al₂O₃ film having a thickness of less than 1 nm.

As illustrated in FIG. 4C, a switching oxide layer 430 may be fabricated on the interface layer 422. The switching oxide layer 430 may include one or more transition metal oxides, such as TaOₓ, HfOₓ, TiOₓ, NbOx, ZrOx, etc., in binary oxides, ternary oxides, and high-order oxides, wherein x may be used to indicate the oxide being oxygen deficient compared to its full (or terminal) oxide and the value of x may be varied from the oxygen to metal atomic ratio in the stoichiometry of its full oxide, such as x≤2.0 for HfOₓ (where HfO₂ being the full oxide), and x≤2.5 for TaOₓ (where Ta₂O₅ being the full oxide). As an example, the switching oxide layer 430 may include Ta₂O₅. As another example, the switching oxide layer 430 may include HfO₂.

In some embodiments, during the fabrication of the switching oxide layer 430, one or more portions of the transition metal oxides may be disposed on the first electrode 420 through one or more pores/pin-holes 424. As such, the switching oxide layer 430 may directly contact one or more portions of the first electrode 420.

As shown in FIG. 4D, a second electrode 440 may be fabricated on the switching oxide layer 430. In some embodiments, the second electrode 440 may include the second electrode 340 as described in connection with FIGS. 3C-3D.

FIGS. 4E and 4F illustrate RRAM devices 400e and 400f corresponding to a low-resistance state and a high-resistance state of RRAM device 400d, respectively. The incorporation of the interface layer 422 may reduce the contact area between the switching oxide layer 430 and the first electrode 420. As illustrated in FIG. 4E, a conductive channel 435a comprising Ru (e.g., a filament of Ru) may be formed from the second electrode 440 to the first electrode 420 through the interface layer 422 and the switching oxide layer 430. As illustrated in FIG. 4F, an interrupted conductive channel 435b of Ru may be formed in the switching oxide layer 430 during the reset process. The incorporation of the interface layer 422 into the RRAM device may result in a less abrupt forming process, reduce the forming voltage, reduce the reset current, and reduce voltage and/or current requirements in subsequent operation processes.

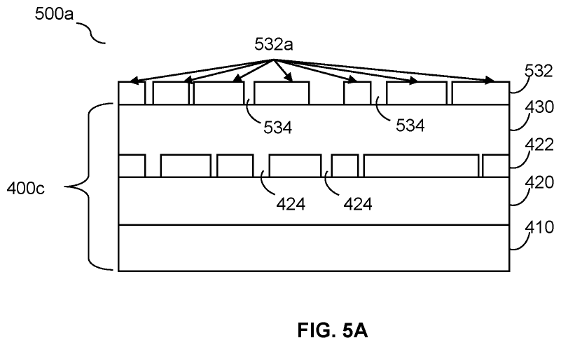

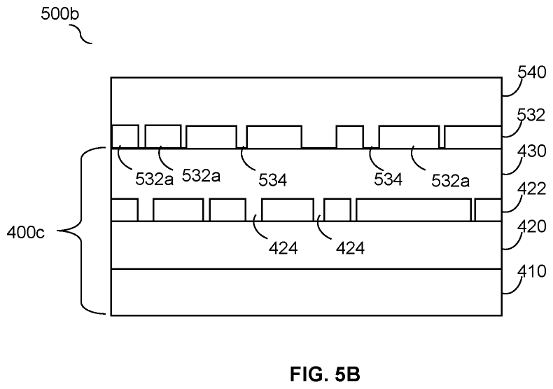

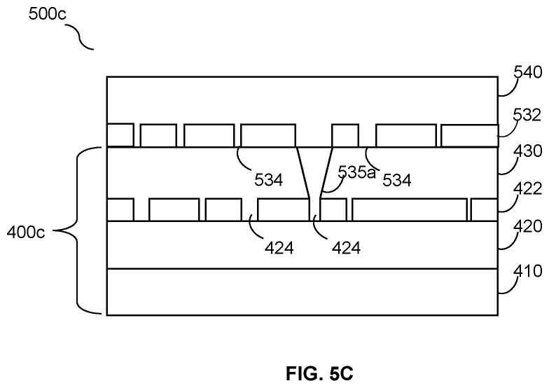

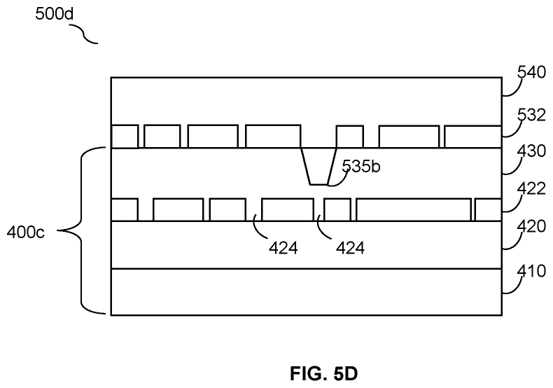

In some embodiments, an RRAM device may include multiple interface layers fabricated between the first electrode and the second electrode. Each of the interface layers may include a discontinuous film as described in connection with FIG. 4B. For example, as illustrated in FIG. 5A, a semiconductor device 500a may be fabricated by fabricating an interface layer 532 (also referred to as the “second interface layer”) on the structure 400c as described in connection with FIG. 4C. In some embodiments, the second interface layer 532 may include a discontinuous film 532a of a second dielectric material. The second dielectric material may be more chemically stable than the transition metal oxide in the switching oxide layer 430. As an example, the second dielectric material may include Al₂O₃, SiO₂, Si₃N₄, MgO, Y₂O₃, Gb₂O₃, Sm₂O₃, CeO₂, Er₂O₃, La₂O₃, etc. The second dielectric material may or may not be the same as the first dielectric material.

The discontinuous film 532a may include one or more pores and/or pin-holes 534 (also referred to as the “one or more second pores and/or pin-holes”). The pore(s) 534 may have any suitable size and/or dimension. Multiple pores 534 may or may not have the same size and/or dimension. In some embodiments, the second interface layer 532 and/or the second discontinuous film 532a may include multiple pores 534 dispersed randomly on the second interface layer 532. The discontinuous film 532a may include any suitable number of pores and/or pin-holes.

In some embodiments, a thickness of the second interface layer 532 and/or the second discontinuous film (also referred to as the “second thickness”) may be between about 0.2 nm and about 0.5 nm. As another example, the second interface layer 532 may include a discontinuous Al₂O₃ film having a thickness equal to or less than 0.5 nm. In some embodiments, the second interface layer 532 may include a discontinuous Al₂O₃ film having a thickness less than 1 nm. The second thickness of the second interface layer 532 may or may not be the same as the first thickness of the first interface layer 422.

As illustrated in FIG. 5B, a second electrode 540 may be fabricated on the second interface layer 532 to fabricate an RRAM device 500b. The second interface layer 532 is positioned between the switching oxide layer 430 and the second electrode 540. The second electrode 540 may be and/or include the second electrode 340 as described in conjunction with FIGS. 3C-3D. In some embodiments, during the fabrication of the second electrode 540, one or more portions of the second electrode 540 may be disposed on the switching oxide layer 430 through one or more pores and/or pin-holes 534. That is, at least some of the Ru in the second electrode 540 is deposited on the switching oxide layer 430 through pores and/or pin-holes 534. As such, the second electrode 540 may directly contact one or more portions of the switching oxide layer 430 through one or more pores/pin-holes 534.

FIGS. 5C and 5D illustrate semiconductor devices 500c and 500d that may correspond to a low-resistance state and a high-resistance state of the RRAM device 500b, respectively. The incorporation of both the first interface layer 422 and the second interface layer 532 may further reduce the contact area between the switching oxide layer 430 and the first electrode 420 and the contact area between the switching oxide layer 430 and the second electrode 540. As illustrated in FIG. 5C, a conductive channel 535a of Ru (e.g., a Ru filament) may be formed from the second electrode 540 to the first electrode 420 through the second interface layer 532, the switching oxide layer 430, and the first interface layer 420. As illustrated in FIG. 5D, an interrupted conductive channel 535b of Ru may be formed in the switching oxide layer 430 during the reset process.

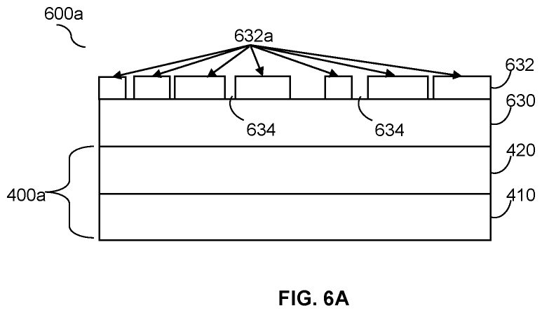

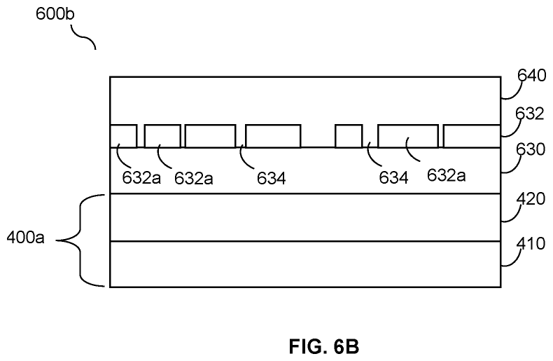

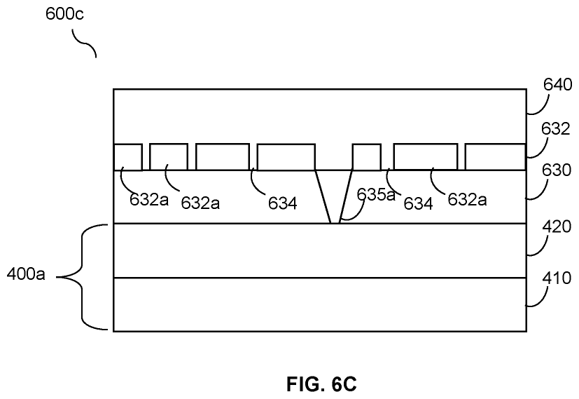

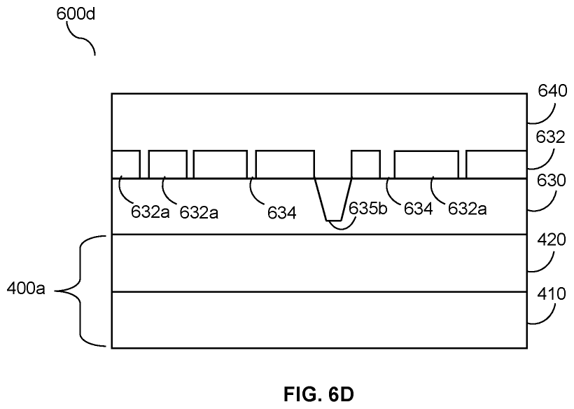

In some embodiments, an interface layer may be fabricated on a switching oxide layer of an RRAM device in accordance with some embodiments of the present disclosure. For example, as illustrated in FIG. 6A, a switching oxide layer 630 may be fabricated on the structure 400a as described in FIG. 4A. An interface layer 632 may be fabricated on the switching oxide layer 630 to fabricate an RRAM device 600a. The switching oxide layer 630 may be and/or include the switching oxide layer 430 as described in conjunction with FIGS. 4C-4D. In some embodiments, the interface layer 632 may include a discontinuous film of a dielectric material. The dielectric material may be more chemically stable than the transition metal oxide in the switching oxide layer 630. As an example, the dielectric material may include Al₂O₃, MgO, Y₂O₃, La₂O₃, etc.

The discontinuous film 632a may include one or more pores and/or pin-holes 634. The pores/pin-holes 634 may have any suitable size and/or dimension and may be dispersed randomly on the interface layer 632. In some embodiments, a thickness of the interface layer 632 (also referred to as the “third thickness”) may be between about 0.2 nm and about 0.5 nm. As another, the interface layer 632 may have a thickness equal to or less than 0.5 nm thickness. As a further example, the interface layer 632 may have a thickness of less than 1 nm.

As illustrated in FIG. 6B, a second electrode 640 may be fabricated on the interface layer 632 to fabricate an RRAM device 600b. The interface layer 632 may thus be positioned between the switching oxide layer 630 and the second electrode 640. The second electrode 640 may be and/or include the second electrode 440 as described in conjunction with FIGS. 4D-4F. In some embodiments, during the fabrication of the second electrode 640, one or more portions of the second electrode 640 may be disposed on the switching oxide layer 630 through pores and/or pin-holes 634 and directly contact the switching oxide layer 630. As such, at least some of the Ru in the second electrode 640 is deposited on the switching oxide layer 630 through the pores and/or pin-holes 634.

FIGS. 6C and 6D illustrate RRAM devices 600c and 600d corresponding to a low-resistance state and a high-resistance state of the RRAM device 600b, respectively. The incorporation of the interface layer 632 may reduce the contact area between the switching oxide layer 630 and the second electrode 640. As illustrated in FIG. 6C, a conductive channel 635a of Ru (e.g., a filament of Ru) may be formed from the second electrode 640 to the first electrode 420 through the switching oxide layer 630 and the interface layer 632. As illustrated in FIG. 6D, an interrupted conductive channel 635b of Ru may be formed in the switching oxide layer 630 during the reset process. The incorporation of the interface layer 632 into the RRAM device may result in a less abrupt forming process, reduce the forming voltage, reduce the reset current, and reduce voltage and/or current requirements in subsequent operation processes.

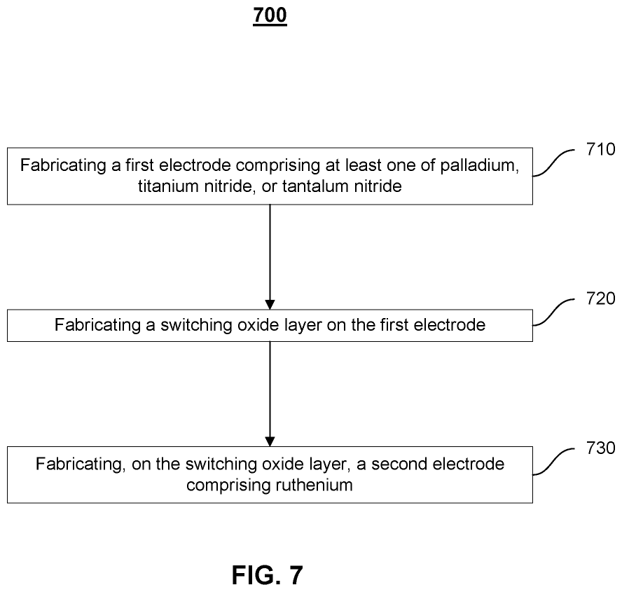

FIG. 7 is a flow diagram illustrating an example 700 of a method for fabricating an RRAM device according to some embodiments of the disclosure, including RRAM device 300c-300d in FIGS. 3C-3D.

At block 710, a first electrode may be fabricated on a substrate. In some embodiments, fabricating the first electrode may involve depositing one or more layers of a metal nitride, such as TiN, TaN, etc. For example, fabricating the first electrode may involve depositing one or more layers of TiN, utilizing an atomic layer deposition (ALD) technique, a physical vapor deposition (PVD) technique, a reactive sputtering of Ti technique, and/or any other suitable deposition technique. In some embodiments, fabricating the first electrode may involve depositing one or more layers of Pd using PVD, chemical vapor deposition (CVD), ALD, and/or other suitable deposition techniques. The first electrode may be and/or include the first electrode 320 as described in connection with FIG. 3A above. In some embodiments, a thin layer of an adhesion material, such as Ti, Ta, etc., may be fabricated between the substrate and the first electrode.

At block 720, a switching oxide layer comprising one or more transition metal oxides may be fabricated on the first electrode. The transition metal oxides may include, e.g., HfOₓ. For example, fabricating the switching oxide layer may involve depositing HfOₓ, utilizing an atomic layer deposition (ALD) technique, a physical vapor deposition (PVD) technique, a reactive sputtering of Hf technique, and/or any other suitable deposition technique. The switching oxide layer may be and/or include switching oxide layer 330 as described in connection with FIG. 3B above.

At block 730, a second electrode may be fabricated on the switching oxide layer. Fabricating the second electrode may involve fabricating one or more layers of one or more metallic materials that are electronically conductive and reactive to the switching oxide. For example, fabricating the second electrode may involve depositing one or more layers of Ru, utilizing CVD, ALD, PVD, and/or any other suitable deposition technique. In some embodiments, fabricating the second electrode may further involve fabricating a layer of a CMOS-compatible metal and/or a CMOS-compatible nitride. The second electrode may be and/or include second electrode 340 as described in connection with FIGS. 3C-3D above.

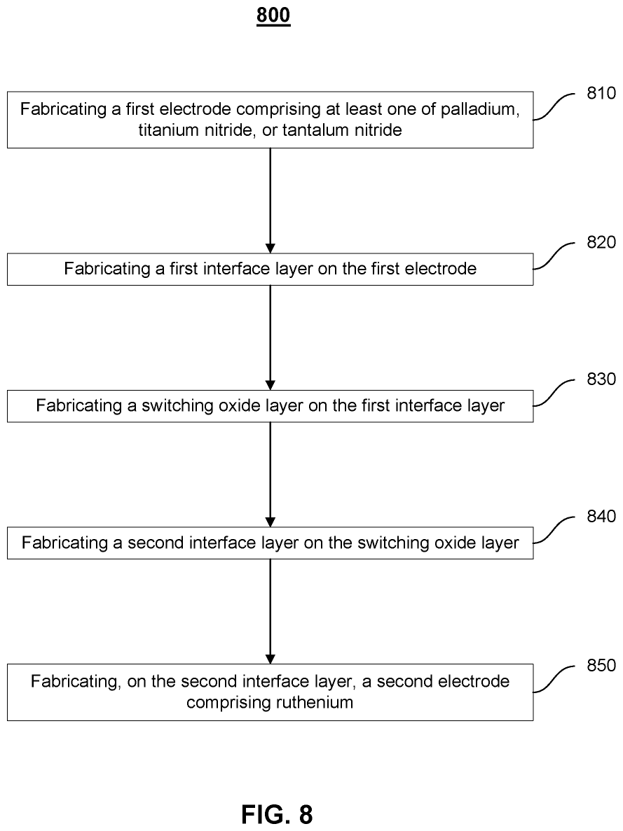

FIG. 8 is a flow diagram illustrating an example 800 of a process for fabricating an RRAM device according to some embodiments of the disclosure, including RRAM device 500b in FIG. 5B.

At block 810, a first electrode may be fabricated on a substrate. Blocks 810 and 710 may be executed in substantially the same manner. The first electrode may be and/or include first electrode 420 as described in connection with FIG. 5B above.

At block 820, a first interface layer may be fabricated on the first electrode. The first interface layer may include a material that is more chemically stable than the transition metal oxide(s) of the switching oxide layer (such as AlOₓ, like Al₂O₃) described subsequently. For example, fabricating the first interface layer may involve depositing AlOₓ, utilizing an atomic layer deposition (ALD) technique, a physical vapor deposition (PVD) technique, a reactive sputtering of Al technique, and/or any other suitable deposition technique. The first interface layer may be and/or include the interface layer 422 as described in connection with FIG. 5B above.

At block 830, a switching oxide layer comprising one or more transition metal oxides may be fabricated on the first interface layer. The transition metal oxides may include, e.g., HfOₓ. For example, fabricating the switching oxide layer may involve depositing HfOₓ, utilizing an ALD technique, a PVD technique, a reactive sputtering of Hf technique, and/or any other suitable deposition technique. The switching oxide layer may be and/or include switching oxide layer 430 as described in connection with FIG. 5B above.

At block 840, a second interface layer may be fabricated on the switching oxide layer. The second interface layer may include a material that is more chemically stable than the transition metal oxide(s) of the switching oxide layer, such as AlOₓ. like Al₂O₃. For example, fabricating the second interface layer may involve depositing AlOₓ, utilizing an ALD technique, a physical vapor deposition (PVD) technique, a reactive sputtering of Al technique, and/or any other suitable deposition technique. The first interface layer may be and/or include the interface layer 532 as described in connection with FIG. 5B above.

At block 850, a second electrode may be fabricated on the second interface layer. Fabricating the second electrode may involve fabricating one or more layers of Ru and/or one or more layers of CMOS-compatible metals and/or nitrides. For example, fabricating the second electrode may involve depositing one or more layers of Ru on the second interface layer, utilizing CVD, ALD, PVD, and/or any other suitable deposition technique. In some embodiments in which the second interface layer includes a discontinuous film of a dielectric layer, at least some Ru is directly deposited on the switching oxide layer through the pores and/or pinholes in the second interface layer. In some embodiments, fabricating the second electrode may further involve fabricating a layer of a CMOS-compatible metal and/or a CMOS-compatible nitride. The second electrode may be and/or include the second electrode 540 as described in connection with FIG. 5B above.

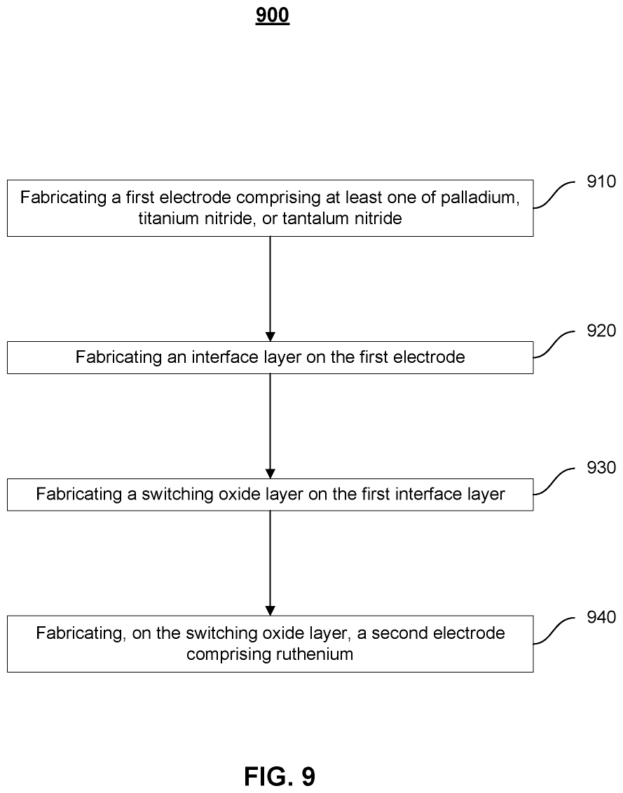

FIG. 9 is a flow diagram illustrating an example 900 of a process for fabricating an RRAM device according to some embodiments of the disclosure, including RRAM device 400d in FIG. 4D.

At block 910, a first electrode may be fabricated on a substrate. Blocks 910 and 710 may be executed in substantially the same manner. The first electrode may be and/or include first electrode 420 as described in connection with FIG. 4D above.

At block 920, an interface layer may be fabricated on the first electrode. The first interface layer may include a material that is more chemically stable than the transition metal oxide(s) of the switching oxide layer (such as AlOₓ, like Al₂O₃) described subsequently. For example, fabricating the first interface layer may involve depositing AlOₓ, utilizing an atomic layer deposition (ALD) technique, a physical vapor deposition (PVD) technique, a reactive sputtering of Al technique, and/or any other suitable deposition technique. The first interface layer may be and/or include the interface layer 422 as described in connection with FIG. 4D above.

At block 930, a switching oxide layer comprising one or more transition metal oxides may be fabricated on the first interface layer. The transition metal oxides may include, e.g., HfOₓ. For example, fabricating the switching oxide layer may involve depositing HfOₓ, utilizing an ALD technique, a PVD technique, a reactive sputtering of Hf technique, and/or any other suitable deposition technique. The switching oxide layer may be and/or include switching oxide layer 430 as described in connection with FIG. 4D above.

At block 940, a second electrode may be fabricated on the switching oxide layer. Fabricating the second electrode may involve fabricating one or more layers of Ru and/or one or more layers of CMOS-compatible metals and/or nitrides. Blocks 940 and 730 may be executed in substantially the same manner. The second electrode may be and/or include second electrode 440 as described in connection with FIG. 4D above.

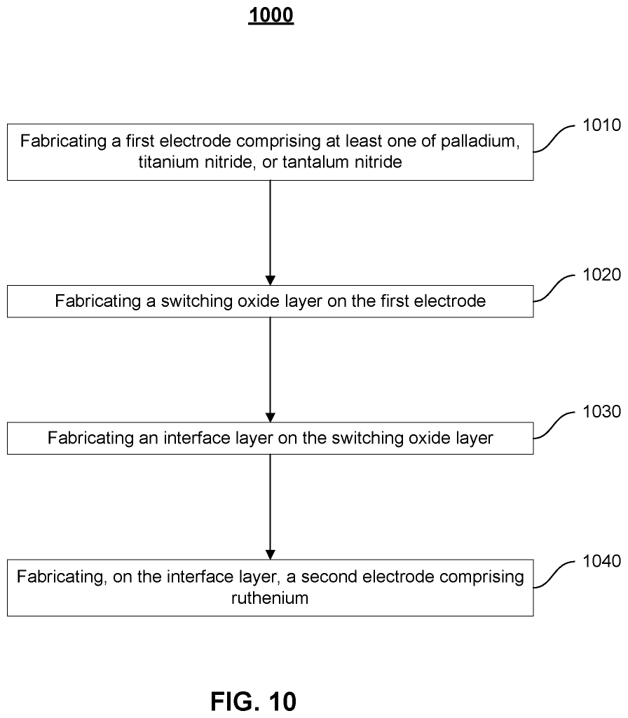

FIG. 10 is a flow diagram illustrating an example 1000 of a process for fabricating an RRAM device according to some embodiments of the disclosure, including RRAM device 600b in FIG. 6B.

At block 1010, a first electrode may be fabricated on a substrate. Blocks 1010 and 710 may be executed in substantially the same manner. The first electrode may be and/or include first electrode 420 as described in connection with FIG. 6B above.

At block 1020, a switching oxide layer comprising one or more transition metal oxides may be fabricated on the first interface layer. The transition metal oxides may include, e.g., HfOₓ. For example, fabricating the switching oxide layer may involve depositing HfOₓ, utilizing an ALD technique, a PVD technique, a reactive sputtering of Hf technique, and/or any other suitable deposition technique. The switching oxide layer may be and/or include switching oxide layer 630 as described in connection with FIG. 6B above.

At block 1030, an interface layer may be fabricated on the switching oxide layer. The second interface layer may include a material that is more chemically stable than the transition metal oxide(s) of the switching oxide layer, such as AlOₓ like Al₂O₃. For example, fabricating the second interface layer may involve depositing AlOₓ, utilizing an ALD technique, a physical vapor deposition (PVD) technique, a reactive sputtering of Al technique, and/or any other suitable deposition technique. The second interface layer may be and/or include the interface layer 632 as described in connection with FIG. 6B above.

At block 1040, a second electrode may be fabricated on the second interface layer. Fabricating the second electrode may involve fabricating one or more layers of Ru and/or one or more layers of CMOS-compatible metals and/or nitrides. Blocks 1040 and 850 may be executed in substantially the same manner. The second electrode may be and/or include the second electrode 640 as described in connection with FIG. 6B above.

FIG. 11 is a Pd—Ru binary phase diagram 1100. According to diagram 1100, the Pd solid phase and the Ru solid phase are immiscible, meaning that they do not tend to form a solid solution. This means that the solubility of Ru in Pd is very low, approximately 2 at % at 500° C., and may be substantially lower at lower temperature.

For simplicity of explanation, the methods of this disclosure are depicted and described as a series of acts. However, acts in accordance with this disclosure can occur in various orders and/or concurrently, and with other acts not presented and described herein. Furthermore, not all illustrated acts may be required to implement the methods in accordance with the disclosed subject matter. In addition, those skilled in the art will understand and appreciate that the methods could alternatively be represented as a series of interrelated states via a state diagram or events.

The terms “approximately,” “about,” and “substantially” as used herein may mean within a range of normal tolerance in the art, such as within 2 standard deviations of the mean, within ±20% of a target dimension in some embodiments, within ±10% of a target dimension in some embodiments, within ±5% of a target dimension in some embodiments, within ±2% of a target dimension in some embodiments, within ±1% of a target dimension in some embodiments, and yet within ±0.1% of a target dimension in some embodiments. The terms “approximately” and “about” may include the target dimension. Unless specifically stated or obvious from context, all numerical values described herein are modified by the term “about.”

As used herein, a range includes all the values within the range. For example, a range of 1 to 10 may include any number, combination of numbers, sub-range from the numbers of 1, 2, 3, 4, 5, 6, 7, 8, 9, and 10 and fractions thereof.

In the foregoing description, numerous details are set forth. It will be apparent, however, that the disclosure may be practiced without these specific details. In some instances, well-known structures and devices are shown in block diagram form, rather than in detail, in order to avoid obscuring the disclosure.

The terms “first,” “second,” “third,” “fourth,” etc. as used herein are meant as labels to distinguish among different elements and may not necessarily have an ordinal meaning according to their numerical designation.

The words “example” or “exemplary” are used herein to mean serving as an example, instance, or illustration. Any aspect or design described herein as “example” or “exemplary” is not necessarily to be construed as preferred or advantageous over other aspects or designs. Rather, use of the words “example” or “exemplary” is intended to present concepts in a concrete fashion. As used in this application, the term “or” is intended to mean an inclusive “or” rather than an exclusive “or”. That is, unless specified otherwise, or clear from context, “X includes A or B” is intended to mean any of the natural inclusive permutations. That is, if X includes A; X includes B; or X includes both A and B, then “X includes A or B” is satisfied under any of the foregoing instances. In addition, the articles “a” and “an” as used in this application and the appended claims should generally be construed to mean “one or more” unless specified otherwise or clear from context to be directed to a singular form. Reference throughout this specification to “an implementation” or “one implementation” means that a particular feature, structure, or characteristic described in connection with the implementation is included in at least one implementation. Thus, the appearances of the phrase “an implementation” or “one implementation” in various places throughout this specification are not necessarily all referring to the same implementation.

As used herein, when an element or layer is referred to as being “on” another element or layer, the element or layer may be directly on the other element or layer, or intervening elements or layers may be present. In contrast, when an element or layer is referred to as being “directly on” another element or layer, there are no intervening elements or layers present.

Whereas many alterations and modifications of the disclosure will no doubt become apparent to a person of ordinary skill in the art after having read the foregoing description, it is to be understood that any particular embodiment shown and described by way of illustration is in no way intended to be considered limiting. Therefore, references to details of various embodiments are not intended to limit the scope of the claims, which in themselves recite only those features regarded as the disclosure.

What is claimed is:

1. A resistive random-access memory (RRAM) device, comprising:
a first electrode comprising at least one of palladium, titanium nitride, or tantalum nitride;
a second electrode comprising ruthenium; and
a switching oxide layer fabricated between the first electrode and the second electrode, wherein the switching oxide layer comprises at least one transition metal oxide.

2. The RRAM device of claim 1, wherein the transition metal oxide comprises at least one of HfOₓ or TaO_{y}, wherein x≤2.0, and wherein y≤2.5.

3. The RRAM device of claim 2, wherein the switching oxide layer further comprises a dopant oxide that is more chemically stable than the at least one transition metal oxide.

4. The RRAM device of claim 3, wherein the dopant oxide comprises at least one of Al₂O₃, SiO₂, ZrO₂, Sc₂O₃, or Y₂O₃.

5. The RRAM device of claim 1, wherein the second electrode further comprises a layer of at least one of a CMOS-compatible metal or a CMOS-compatible nitride, wherein the CMOS-compatible metal comprises at least one of tungsten, titanium, aluminum, or copper, and wherein the CMOS-compatible nitride comprises at least one of silicon nitride, aluminum nitride, tantalum nitride, or titanium nitride.

6. The RRAM device of claim 1, further comprising an interface layer positioned between the switching oxide layer and the second electrode, wherein the second electrode comprising ruthenium is fabricated on the interface layer.

7. The RRAM device of claim 6, wherein the interface layer positioned between the switching oxide layer and the second electrode comprises a non-continuous film of a dielectric material, wherein at least a portion of the ruthenium in the second electrode is deposited on the switching oxide layer.

8. The RRAM device of claim 1, further comprising a first interface layer positioned between the first electrode and the switching oxide layer.

9. The RRAM device of claim 8, further comprising a second interface layer positioned between the second electrode and the switching oxide layer.

10. The RRAM device of claim 1, wherein a conductive channel comprising ruthenium is formed in the switching oxide layer in response to an application of a programming voltage to the RRAM device.

11. A method for fabricating an RRAM device, comprising:
fabricating a first electrode comprising at least one of palladium, titanium nitride, or tantalum nitride;
fabricating a switching oxide layer on the first electrode, wherein the switching oxide layer comprises at least one transition metal oxide; and
fabricating a second electrode comprising ruthenium.

12. The method of claim 11, wherein the transition metal oxide comprises at least one of HfOₓ or TaO_{y}, wherein x≤2.0, and wherein y≤2.5.

13. The method of claim 12, wherein the switching oxide layer further comprises a dopant oxide that is more chemically stable than the at least one transition metal oxide.

14. The method of claim 13, wherein the dopant oxide comprises at least one of Al₂O₃, SiO₂, ZrO₂, Sc₂O₃, or Y₂O₃.

15. The method of claim 11, wherein fabricating the second electrode further comprises fabricating a layer of ruthenium.

16. The method of claim 11, wherein fabricating the second electrode further comprises fabricating a layer of at least one of a CMOS-compatible metal or a CMOS-compatible nitride, wherein the CMOS-compatible metal comprises at least one of tungsten, titanium, aluminum, or copper, wherein the CMOS-compatible nitride comprises at least one of silicon nitride, aluminum nitride, tantalum nitride, or titanium nitride.

17. The method of claim 11, further comprising fabricating an interface layer on the switching oxide layer, wherein fabricating the second electrode comprises depositing ruthenium on the interface layer.

18. The method of claim 16, wherein the interface layer comprises a non-continuous film of a dielectric material, wherein at least a portion of the ruthenium in the second electrode is deposited on the switching oxide layer.

19. The method of claim 17, wherein the dielectric material comprises at least one of Al₂O₃, SiO₂, ZrO₂, Sc₂O₃, or Y₂O₃.

20. The method of claim 11, further comprising:
fabricating a first interface layer comprising a first dielectric material on the first electrode, wherein the switching oxide layer is fabricated on the first interface layer; and
fabricating a second interface layer comprising a second dielectric material on the switching oxide layer, wherein the second electrode is fabricated on the second interface layer.
